(19) United States
(12) Patent Application Publication
(10) Pub. No.: US 2010/0084187 A1
(43) Pub. Date: Apr. 8, 2010

(54) COUPLER

(75) Inventor: John Pearson, Glasgow (GB)

Correspondence Address: Workman Nydegger;1000 Eagle Gate Tower, 60 East South Temple, Salt Lake City, UT, 84111, US

(73) Assignee: Diagnostic Monitoring Systems Limited, Glasgow (GB)

(21) Appl. No.: 12/444,222

(22) PCT Filed: Oct. 5, 2007
(86) PCT No.: PCT/GB07/03777

§ 371 Date: Dec. 1, 2009

(30) Foreign Application Priority Data
Oct. 5, 2006 (GB) 0619690.1

(51) Int. Cl. H01L 23/06

(52) U.S. Cl. 174/565

(57) ABSTRACT

A coupler that aids in the detection of partial discharge events in a vessel. The coupler comprises a housing for a detector which extends through a wall of the vessel. The housing is sealably connectable to a vessel and is at least partially transparent to electromagnetic radiation. The coupler may be used to allow monitoring of partial discharge events in such vessels as gas and oil insulated subsystems, gas and oil insulated transformers, and gas and oil insulated cables and cable terminations.

The present invention relates to an improved coupler and in particular to a coupler that aids in the detection of partial discharge events in a vessel.

In the field of electrical engineering, the detection and subsequent analysis of partial discharges within complex apparatus is used to predict breakdown of electrical components. A partial discharge (PD) is caused by dielectric breakdown of insulation material in the presence of a large electric field. One example of such apparatus is that of Gas Insulated Switchgear (GIS) in which sulphur hexafluoride (SF₆) is used as an insulating. gas. Alternatively, oil insulation may be used, for example in High Voltage Transformers.

It is known that partial discharges may, over time, cause breakdown of the dielectric insulator material. PD detection is therefore carried out throughout the lifetime of such electrical apparatus in order to determine if breakdown is occurring. This is especially important as, unmonitored, a piece of equipment exhibiting partial discharges is likely to experience full breakdown and, given the high voltage nature of many of these kinds of apparatus, ultimately explode.

The ideal way to detect such partial discharge events is to house an appropriate detector within the apparatus itself. This detector is adapted to measure electromagnetic radiation corresponding to partial discharge events within the apparatus.

The components of high voltage apparatus are typically immersed in an insulating fluid. Maintaining the integrity of the fluid (i.e. keeping it free from impurities, etc.) is vitally important in prolonging the life of the apparatus. It is therefore difficult to house and to maintain detectors within the apparatus without adversely affecting the insulating fluid. Furthermore, the processes involved in housing and maintaining the detectors are costly to implement and contain risk to the future operation of the apparatus.

Alternatively, the detector may be located externally to the apparatus, for example adjacent to a transparent window through which electromagnetic radiation corresponding to a partial discharge event may be detected.

Although this detector location does not risk contamination of the insulating fluid, the disadvantage of this technique is that the detector is not in an optimum position to detect the electromagnetic radiation. Furthermore, dependent on the type of window used, the electromagnetic signal may undergo significant losses, and given the highly sensitive nature of these measurements this may be reflected in a poorer degree of sensitivity.

It is an object of the present invention to provide an improved coupler.

According to a first aspect of the present invention, there is provided a coupler for coupling electromagnetic radiation corresponding to a partial discharge event, the coupler comprising:
a housing sealably connectable to a vessel, the housing at least partially transparent to electromagnetic radiation and adapted to receive a detector; and
wherein the housing is adapted to extend through a wall of the vessel.

This coupler allows a detector to be located effectively within the vessel while remaining external to the vessel. Improved detection of electromagnetic radiation corresponding to partial discharge events can thus be achieved without the risk of contaminating the contents of the vessel (e.g. insulating fluid, components) such as that resulting from material mismatch with the detector or breakage of the detector resulting from vibration of the apparatus.

Preferably, the housing comprises an elongate portion which extends through the wall of the vessel, the elongate portion having a blind bore adapted to receive the detector. The blind bore may be a snug fit or interference fit for the detector. Preferably, locating the detector in the blind bore physically separates the detector from the contents of the vessel.

Preferably, the housing is transparent to electromagnetic radiation corresponding to partial discharge events. The material of the housing is selected to minimise the attenuation of the electromagnetic radiation.

Preferably, the housing further comprises a flange member which provides the sealable connection to the vessel wall. Preferably the flange member further provides a fluid seal with the vessel wall. The flange member may be adapted for coupling to inspection ports, flanges, or corresponding apertures on the vessel wall.

Preferably, the flange member is disposed at the mouth of the blind bore. Preferably the flange member and the blind bore are integrated to form a single unitary member.

Optionally, the housing further comprises a sealing plate for closeable connection with the flange member so as to sealably enclose a detector. Preferably the sealing plate further provides electromagnetic shielding to a detector.

According to a second aspect of the present invention there is provided a coupling assembly comprising:
a detector;
wherein the detector is located within the coupler of the first aspect.

Preferably, the detector is a UHF detector.

According to a third aspect of the present invention there is provided an appararus comprising:
a vessel;
wherein the coupling assembly of the second aspect is sealably connected to the vessel and the housing extends through a wall of the vessel.

Preferably, the vessel is selected from the group comprising gas and oil insulated subsystems, gas and oil insulated transformers, and gas and oil insulated cables and cable terminations.

The present invention will now be described by way of example only and with reference to the accompanying figures in which:

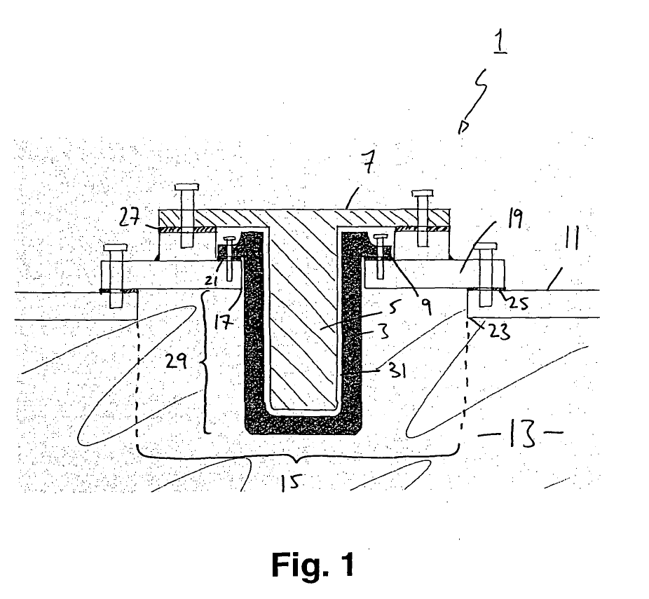

FIG. 1 illustrates a cross-sectional view of a detector assembly in accordance with an aspect of the present invention.

With reference to FIG. 1, there is presented a detector assembly 1 that functions to provide improved detection of electromagnetic radiation corresponding to partial discharge events as described in detail below. The assembly 1 comprises a detector housing 3, a detector 5 located within the housing 3 and a sealing plate 7 to seal the detector 5 within the housing 3. The housing 3 has a flange member 9 which may bolted directly onto the wall 11 of a vessel 13 containing an insulating fluid. The vessel 13 may be (for example) a gas insulated subsystem or an oil filled transformer.

In the illustrated embodiment, the detector assembly 1 is configured for mounting onto the vessel wall 11 through an access port 15. The detector housing 3 is located through a corresponding aperture 17 of an access port plate 19 such that the flange member 9 overlaps the edge of the aperture 17 where it is bolted into place. A fluid seal 21 is provided by this engagement which prevents insulating fluid from escaping from the vessel 13 or being contaminated by external materials.

The access port plate 19 is bolted over the outer rim 23 of the access port 15, also providing a fluid seal 25 preventing leakage of any insulating fluid.

The sealing plate 7 is bolted in place over the housing 3 and detector 5 so as to provide a fluid seal 27 around the detector 5. Furthermore, the sealing plate 7 provides electromagnetic shielding to the detector 5 to prevent external equipment etc. from interfering with the operation of the detector 5. A sealed connection port may be located on the sealing plate 7 to allow the detector 5 to be coupled to external electronics.

An elongate portion 29 of the detector housing 3 extends into the vessel 13. The elongate portion 29 has a blind bore 31 extending therethrough in which the detector 5 is located. The elongate portion 29 extends sufficiently into the vessel 13 that the detector 5 is effectively surrounded by the insulating fluid within. The material of at least the elongate portion 29 of the housing 3 is transparent to electromagnetic radiation corresponding to partial discharge events within the insulating fluid.

The effect of this arrangement is that the detector 5 is able to operate largely as if it were located within the vessel 13 itself and in physical contact with the insulating fluid—enjoying the associated benefit of the enhanced sensitivity to electromagnetic radiation achieved within the vessel. However, as the detector 5 remains separate from the insulating fluid by means of the detector housing 3, it is possible to remove the detector 5 without adverse effects on the insulating fluid resulting from drainage of the apparatus. Thus, the abovementioned enhanced sensitivity can be achieved while retaining the ability to easily remove and service the detector 5 if need be.

When a partial discharge event occurs, the enclosed space within the vessel resonates, resulting in a UHF signal which can be detected by the detector 5. Ordinarily a detector 5 located outwith the vessel 13 will suffer from reduced sensitivity as it is outwith the resonating volume. However, being able to detect this with higher sensitivity by virtue of being within the resonating volume allows for smaller events to be detected and thus for faults to be determined at an earlier stage.

Again, this can be achieved while still retaining a separation between the detector 5 and the insulating fluid.

In summary, the present invention will allow a detector to achieve sensitivities previously only possible with internal detectors but retaining easy access to the detector itself for repairs etc. without the risk of contamination of the insulating fluid. The present invention therefore combines the technical convenience of a detector located outwith an apparatus and the operational advantages of a detector located internal to the apparatus.

This detector housing is envisaged as being of great utility in detecting partial discharge events in oil filled transformers.

Further modifications and improvements may be added without departing from the scope of the invention herein described. For example, the detector need not be a UHF detector, but can be any detector capable of detecting an electromagnetic signal corresponding to a partial discharge event.

1. A coupler for coupling electromagnetic radiation corresponding to a partial discharge event, the coupler comprising:
a housing sealably connectable to a vessel, the housing at least partially transparent to electromagnetic radiation and adapted to receive a detector; and
wherein the housing is adapted to extend through a wall of the vessel.

2. A coupler as claimed in claim 1 wherein, the housing comprises an elongate portion which extends through the wall of the vessel, the elongate portion having a blind bore adapted to receive the detector.

3. A coupler as claimed in claim 2 wherein, the blind bore is a snug fit for the detector.

4. A coupler as claimed in claim 2 wherein, the blind bore is an interference fit for the detector.

5. A coupler as claimed in claim 2 wherein, locating the detector in the blind bore physically separates the detector from the contents of the vessel.

6. A coupler as claimed in claim 1 wherein, the housing is transparent to electromagnetic radiation corresponding to partial discharge events.

7. A coupler as claimed in claim 1 wherein, the material of the housing is selected to minimise the attenuation of the electromagnetic radiation.

8. A coupler as claimed in claim 1 wherein, the housing further comprises a flange member which provides the sealable connection to the vessel wall.

9. A coupler as claimed in claim 8 wherein, the flange member further provides a fluid seal with the vessel wall.

10. A coupler as claimed in claim 8 wherein, the flange member is adapted for coupling to inspection ports, flanges, or corresponding apertures on the vessel wall.

11. A coupler as claimed in claim 2 wherein, the housing further comprises a flange member which provides the sealable connection to the vessel wall, wherein the flange member is disposed at the mouth of the blind bore.

12. A coupler as claimed in claim 11 wherein, the flange member and the blind bore are integrated to form a single unitary member.

13. A coupler as claimed in claim 8, wherein the housing further comprises a sealing plate for closeable connection with the flange member so as to sealably enclose a detector.

14. A coupler as claimed in claim 13 wherein, the sealing plate further provides electromagnetic shielding to a detector.

15. A coupling assembly comprising:
a coupler comprising
a housing sealably connectable to a vessel, the housing at least partially transparent to electromagnetic radiation and adapted to receive a detector, and
wherein the housing is adapted to extend through a wall of the vessel; and
a detector located within the coupler.

16. A coupling assembly as claimed in claim 15 wherein, the detector is a UHF detector.

17. An apparatus comprising:
a vessel; and
a coupling assembly as claimed in claim 15, wherein the coupling assembly is sealably connected to the vessel and the housing extends through a wall of the vessel.

18. An apparatus as claimed in claim 17 wherein, the vessel is selected from the group comprising gas and oil insulated subsystems, gas and oil insulated transformers, and gas and oil insulated cables and cable terminations.
